(19) United States
(12) Patent Application Publication
(10) Pub. No.: US 2007/0020941 A1
(43) Pub. Date: Jan. 25, 2007

(54) Plasma etching apparatus and particle removal method

(76) Inventors: Tomoyuki Tamura, Kudamatsu-shi (JP); Kenji Maeda, Kudamatsu-shi (JP); Hiroyuki Kobayashi, Kodaira-shi (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/210,728

(22) Filed: Aug. 25, 2005

(30) Foreign Application Priority Data
Jul. 19, 2005 (JP) 2005-208869

(51) Int. Cl. H01L 21/302; H01L 21/461

(52) U.S. Cl. 438/710

(57) ABSTRACT

The invention provides a particle removal method for a plasma processing apparatus, the method easily removing particles in the chamber up to its lower part. In a plasma etching apparatus including an upper antenna, a lower electrode, pressure gauges P1 and P2, gas introducing means, evacuating means, and phase controlling means for controllably applying RF power at a common frequency to the upper antenna and the lower electrode and for controlling phase of the RF power between equal phase and opposite phase, the particle removal method comprises: during a semiconductor substrate processing, applying RF power to the upper antenna and the lower electrode in opposite phase of voltage; and when the semiconductor substrate is not processed, performing discharge in the presence of non-depositing gas, applied power for the upper antenna and for the lower electrode being in equal phase of voltage and having a voltage amplitude of 100 V or more, and the height of the lower electrode being lower than the height during the semiconductor substrate processing.

The present application is based on and claims priority of Japanese patent application No. 2005-208869 filed on Jul. 19, 2005, the entire contents of which are hereby incorporated by reference.

### BACKGROUND OF THE INVENTION

1. Field of the Invention

This invention relates to a plasma processing apparatus for use in the field of semiconductor manufacture, and more particularly to a plasma processing method capable of reducing particles.

2. Description of the Related Art

Generally, in many plasma etching apparatuses, special functionality for removing particles is not provided. However, there is disclosed a method of cleaning a plasma CVD film forming apparatus by local discharge with a special electrode called “cleaning electrode” (see, e.g., Japanese Laid-Open Patent Application 2002-57110, hereinafter referred to as Patent Document 1). In addition, there is disclosed a method of efficiently removing particles from a plasma processing chamber by decreasing the pressure and increasing the flow rate while applying RF power (see, e.g., Japanese Laid-Open Patent Application 6-84853 (1994), hereinafter referred to as Patent Document 2). Moreover, there is disclosed a method of cleaning by controlling the phase of an RF bias applied to an electrode to spread plasma (see, e.g., Japanese Laid-Open Patent Application 2002-184766, hereinafter referred to as Patent Document 3).

In the method of cleaning a plasma etching apparatus as disclosed in Patent Document 1, addition of a cleaning electrode to the plasma etching apparatus increases apparatus cost due to an extra power supply and other components. The electrode also complicates the structure of the apparatus. Patent Document 1 does not sufficiently clarify how to design the apparatus to avoid residual particles in the interstices of the complicated structure. The material of the components constituting the electrode still requires consideration of metal contamination and consumption cost. On the other hand, while Patent Document 2 discloses decreasing the pressure and Increasing the flow rate in plasma processing, it is only directed to removal of particles in the vicinity of a wafer in the processing chamber. The effect of the method of Patent Document 2 is unknown if any particles are produced in the lower part of the processing chamber. Particles and deposits attached to the lower part of the processing chamber cause gradual increase of the amount of particles when the chamber is used over time on a mass production line. Therefore the particles in the lower part require cleaning. Furthermore, from Patent Document 3, which only refers to the use of phase to spread plasma, suitable discharge conditions other than the phase remain unknown.

An object of the invention is to provide a particle removal method that can easily remove particles in the chamber up to its lower part.

### SUMMARY OF THE INVENTION

In order to solve the above problems, the invention provides a particle removal method in a plasma etching apparatus including an upper antenna and a lower electrode opposed thereto in a vacuum processing chamber, the lower electrode being capable of mounting a semiconductor substrate; a pressure gauge system for monitoring the pressure of the processing chamber during plasma processing; gas introducing means; evacuating means; means for controllably applying RF power at a common frequency to the upper antenna and the lower electrode and for controlling phase of the RF power between equal phase and opposite phase; and means for vertically moving the lower electrode. The method comprises: when a semiconductor substrate is processed, applying RF power to the upper antenna and the lower electrode in opposite phase of voltage; and when the semiconductor substrate is not processed, performing discharge in the presence of non-depositing gas, applied power for the upper antenna and applied power for the lower electrode being in equal phase of voltage, one of the applied powers having a voltage amplitude of 100 V or more, and the height of the lower electrode being lower than the height in which the semiconductor substrate is processed.

By applying RF power to the upper antenna and the lower electrode in opposite phase of voltage during the semiconductor substrate being processed, the upper antenna serves as ground for the lower electrode, and the lower electrode serves as ground for the upper antenna. As a result, the spread of plasma, and hence the consumed area of components, can be kept small. The bias applied to the wall at this time is a plasma potential determined by the plasma density and electron temperature rather than as the ground for the electrode, and is approximately a little less than 50 V.

By applying RF power to the upper antenna and the lower electrode in opposite phase of voltage during the semiconductor substrate being processed, sputtered nonvolatile particles may accumulate slightly outside the plasma expansion region. However, when the semiconductor substrate is not processed, RF power is applied in phase to the upper antenna and the lower electrode in the presence of non-depositing gas at a pressure higher than during the processing. This causes plasma to seek ground on the inner surface of the processing chamber, and to spread to the sidewall and the lower part of the processing chamber, and thereby the particles can be removed.

More specifically, the invention provides a particle removal method in a plasma etching apparatus including an upper antenna and a lower electrode opposed thereto in a vacuum processing chamber, the lower electrode being capable of mounting a semiconductor substrate; gas introducing means; evacuating means; means for controllably applying RF power at a common frequency to the upper antenna and the lower electrode and for controlling voltage phase of the RF power between equal phase and opposite phase; and means for vertically moving the lower electrode, the method comprising: during a semiconductor substrate processing, applying RF power to the upper antenna and the lower electrode in opposite phase of voltage; and when the semiconductor substrate is not processed, performing discharge in the presence of non-depositing gas, applied power for the upper antenna and applied power for the lower electrode being in equal phase of voltage, one of the applied powers having a voltage amplitude of 100 V or more, and the height of the lower electrode being lower than the height in which the semiconductor substrate is processed.

In an aspect of the particle removal method of the invention, the RF power applied in opposite phase has a voltage phase difference of 170° to 190°, and the RF power applied in equal phase has a voltage phase difference of −30° to 30°. In another aspect of the particle removal method of the invention, when the semiconductor substrate is not processed, discharge is performed at a higher pressure than a semiconductor substrate processing pressure. In still another aspect of the particle removal method of the invention, when the semiconductor substrate is not processed, while introduction of the non-depositing gas is continued, the applied power is varied or application and non-application of power are repeated twice or more. In yet another aspect of the particle removal method of the invention, when two or more semiconductor substrates are consecutively processed, introduction of the non-depositing gas is continued between the processes for the semiconductor substrates, and discharge is performed with the pressure of the processing chamber being kept higher than a semiconductor substrate processing pressure.

In another aspect of the particle removal method of the invention, when two or more semiconductor substrates are consecutively processed, while introduction of the non-depositing gas is continued between the processes for the semiconductor substrates, discharge is performed with the pressure of the processing chamber being kept higher than a semiconductor substrate processing pressure, the discharge being such that the applied power is varied or application and non-application of power are repeated twice or more.

The invention provides a plasma etching apparatus comprising: an upper antenna and a lower electrode opposed thereto in a vacuum processing chamber, the lower electrode being capable of mounting a semiconductor substrate; a pressure gauge system for monitoring the pressure of the processing chamber during plasma processing; gas introducing means; evacuating means; and means for controllably applying RF power at a common frequency to the upper antenna and the lower electrode and for controlling voltage phase of the RF power between equal phase and opposite phase, wherein the pressure gauge system has two pressure gauges of different ranges for monitoring the pressure of the processing chamber and includes means for evacuating and zero calibrating each of the pressure gauges without the intervention of the processing chamber even when the processing chamber is not evacuated to high vacuum, and the apparatus performs the above particle removal method. In an aspect of the invention, the plasma etching apparatus further comprises means for vertically moving the lower electrode, and the apparatus performs the above particle removal method. In another aspect of the plasma etching apparatus of the invention, each of the two pressure gauges of different ranges for monitoring the pressure of the processing chamber has a valve to the processing chamber, and between each of the pressure gauges and the valve is provided another valve to evacuation piping, and the apparatus performs the above particle removal method.

As described above, according to the invention, processing is performed by applying RF power in phase to the antenna and the lower electrode, lowering the lower electrode, and increasing the pressure. As a result, particles in the processing chamber can be evacuated and the amount of particles during the semiconductor substrate processing can be reduced.

The present inventors have found by research that during a semiconductor substrate processing, nonvolatile particles produced by the sputtering or etching of the processing chamber wall are likely to accumulate slightly outside the plasma expansion region where the plasma is weakened and its bias to the wall is decreased. The inventors have also found that particles produced during cleaning can be effectively restrained from scattering into the substrate processing section by performing cleaning at an increased pressure.

Moreover, application of electric power having a voltage amplitude of 100 V or more results in a bias of 50 V or more applied to the wall, which is greater than the bias applied to the wall during the semiconductor substrate processing. In this way, more incident energy of ions and electrons can be provided to the remaining particles that are not removed during the semiconductor substrate processing. This increases the thermal stress due to the difference in thermal expansion coefficient of materials of the particles and the wall that have received the incident energy, and electric repulsion due to negative charging of both the particles and the wall, and thereby enables to strip the particles that are not stripped during the semiconductor substrate processing but relatively likely to be stripped.

Furthermore, during a particle removal processing, discharge is performed with the height of the lower electrode being lowered. Therefore plasma is more likely to seek ground and spread in the lower part of the processing chamber, and particles can be stripped in a wider region.

In an aspect of the particle removal method of the invention, discharge is performed at a pressure higher than the semiconductor substrate processing pressure. This pressure, which is set higher than normal processing pressure, more rapidly dampens the momentum that the particles have gained upon being stripped from the wall, and allows the particles to easily follow the flow of gas evacuation. A low pressure would increase the possibility that the stripping momentum may cause the particles to travel upstream into the region where the semiconductor substrate is processed. The higher the pressure, the more effectively the scattering of particles can be prevented. However, the pressure is subjected to the limitation of enabling discharge to occur, and depends on plasma generating methods. In one plasma etching apparatus, a suitable pressure is 20 to 50 Pa.

In this situation, a higher gas flow rate may advantageously increase the rate of evacuating the particles, but has a small effect of preventing the scattering of particles. Therefore increasing the pressure deserves a higher priority.

In another aspect of the invention, the particle removal processing is performed by using non-depositing gas such as a less depositing mixed gas primarily containing CF₄, O₂, NF₃, and SF₆, or by using a mixed gas capable of removing deposits, and thus the particles attached to the wall are not covered with deposition film. Therefore the particles remain to be easily stripped from the wall.

In another aspect of the particle removal method of the invention, while introduction of the non-depositing gas is continued, the applied power is varied, or application and non-application of power are repeated twice or more. As a result, when power is turned on or increased, or is turned off or decreased, the amount of electrons incident on the wall is varied, or the amount of ions in sheath incident on the wall of the processing chamber is varied depending on the varied thickness of the sheath. This causes an abrupt change in the amount of heat input, which results in thermal stress due to a transient thermal expansion distribution of the deposits and the wall. The stress exerts varied force on attachment sites of particles to the wall, thereby further facilitating the stripping of the particles. The stripped particles are moved with the flow of gas and evacuated. In addition, the particles trapped in the plasma sheath during steady discharge can be evacuated with the gas flow when the discharge is turned off.

In another aspect of the particle removal method of the invention, in the case that two or more semiconductor substrates are consecutively processed, when plasma processing is not performed between the processes for the semiconductor substrates, introduction of gas is continued and the pressure of the processing chamber is kept higher than the semiconductor substrate processing pressure. As a result, particles stripped out between the plasma processes can also be moved with the flow of gas and guided along the evacuation direction.

The plasma etching apparatus of this invention comprises a pressure gauge system having two pressure gauges of different ranges for monitoring the pressure of the processing chamber, and means for evacuating and zero calibrating each of the pressure gauges without the intervention of the processing chamber even when the processing chamber is not evacuated to high vacuum. As a result, the pressure gauge of the higher pressure range can be zero calibrated when a semiconductor substrate is processed, and the pressure gauge of the lower pressure range can be zero calibrated when the particle removal processing is performed. Therefore the scattering of particles due to stoppage of gas flow into the processing chamber can be prevented, and the pressure for substrate processing and for particle removal processing can be maintained at a correct value over time.

More specifically, each of the two pressure gauges of different ranges for monitoring the pressure of the processing chamber has a valve to the processing chamber. Between each of the pressure gauges and the valve, another valve to the evacuation piping is provided. As a result, each of the pressure gauges can be zero calibrated irrespective of the pressure of the processing chamber.

### BRIEF DESCRIPTION OF THE DRAWINGS

FIG. 1 is a schematic view of a plasma etching apparatus according to the invention.

FIGS. 2A and 2B are diagrams illustrating the dependence of plasma state on the method of controlling the phase between the antenna and the lower electrode, which show the function of the invention.

FIGS. 3A and 3B are graphical diagrams showing the estimated scattering distance of stripped particles, which show the effect of pressure according to the invention.

FIG. 4 is a flow chart illustrating the process flow of the invention.

### DETAILED DESCRIPTION OF THE PREFERRED EMBODIMENTS

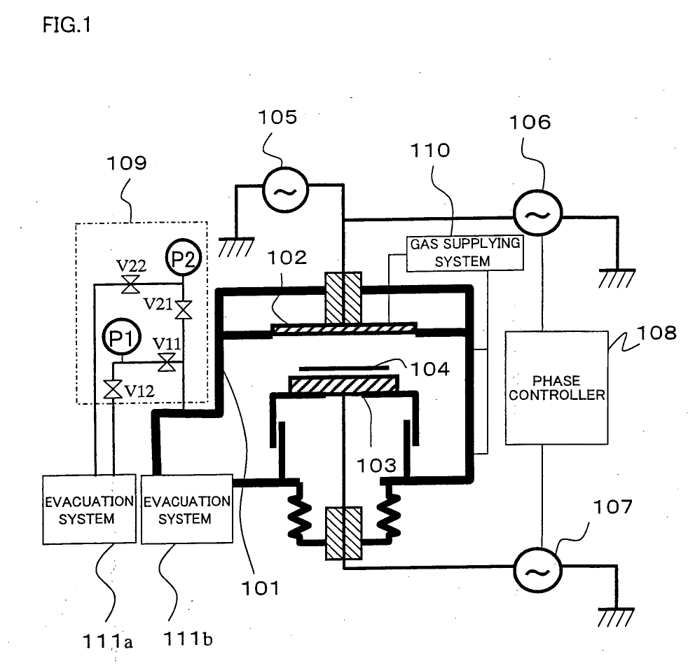

An embodiment of the invention will now be described with reference to the drawings. FIG. 1 shows a schematic view of a plasma etching apparatus according to the invention. The plasma etching apparatus according to the invention comprises an upper antenna 102 and a lower electrode 103 opposed thereto in a processing chamber 101 that can be evacuated. A semiconductor substrate 104 can be mounted on the lower electrode 103. The apparatus further comprises a 200 MHz source RF power supply 105 and an 800 kHz antenna RF power supply 106 for plasma generation, and an 800 kHz lower electrode RF power supply 107. The apparatus also comprises a phase controller 108 for controlling the phase of antenna RF power and lower electrode RF power. The lower electrode 103 is designed so as to be moved vertically. The plasma etching apparatus further includes a pressure monitoring system 109 for monitoring the pressure in the processing chamber 101, a gas supplying system 110 for supplying gas to the processing chamber, and an evacuation system 111b capable of adjusting the evacuation rate. This embodiment includes another evacuation system 111a for evacuating the pressure monitoring system, which may alternatively be shared with the evacuation system for the processing chamber.

The pressure in the processing chamber 101 is measured by the pressure monitoring system 109. The pressure monitoring system 109 comprises a piping connected to the processing chamber 101 via a valve V11 and connected to the evacuation system 111a via a valve V12, a first, low-pressure gauge P1 connected between the valves V11 and V12 on this piping, another piping connected to the processing chamber 101 via a valve V21 and connected to the evacuation system 111a via a valve V22, and a second, high-pressure gauge P2 connected between the valves V21 and V22 on this piping.

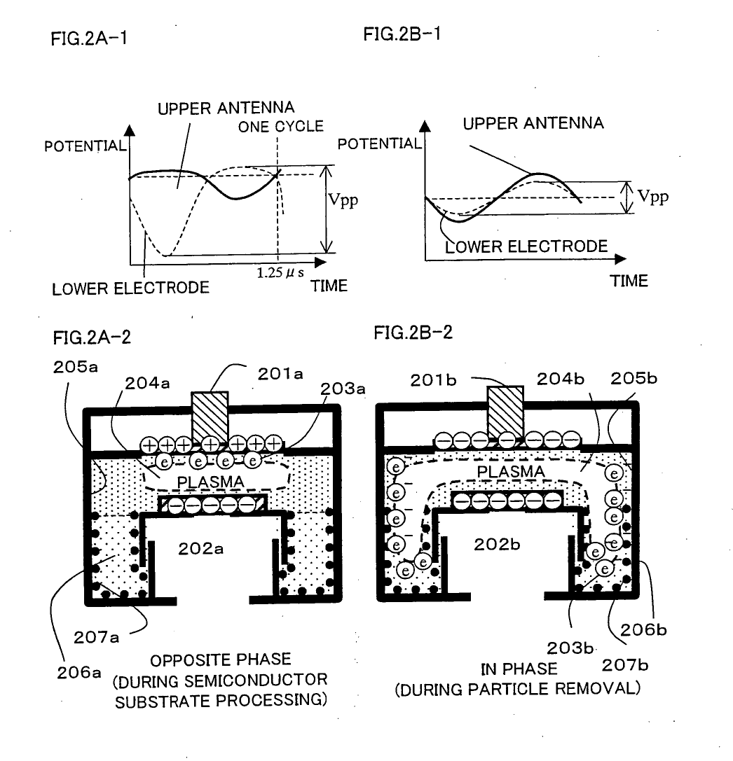

FIGS. 2A and 2B schematically show the dependence of plasma state on the method of controlling the phase between the antenna and the lower electrode. Reference is now made to FIG. 2A-1 for describing the timing of positive and negative potential (solid and dashed lines indicating the upper antenna and the lower electrode, respectively) for one cycle of RF power applied in opposite phase to the upper antenna and the lower electrode during the semiconductor substrate processing.

In FIG. 2A-1 for one cycle of RF power, a voltage Vpp of about 100 to 400 V is applied to the upper antenna, and a voltage Vpp of about 500 to 2000 V is applied to the lower electrode. During the first half cycle in FIG. 2A-1, the upper antenna 201a serves as ground for the lower electrode 202a, causing extra electrons 203a to be incident on the upper antenna, as shown in FIG. 2A-2. As a result, the spread of plasma 204a in the processing chamber is relatively small. With a phase difference of 180°±10°, the energy of ions incident on the processing chamber sidewall 205a is 50 V or less, which is comparable to the plasma potential.

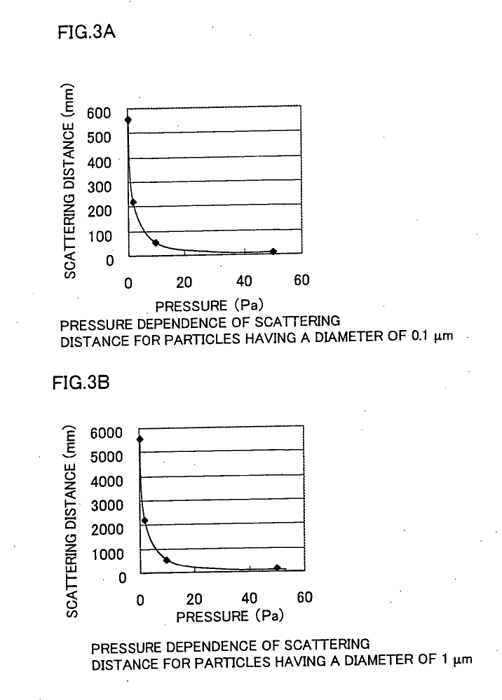

The phase difference dependence of plasma potential is also shown in FIG. 3 of Japanese Laid-Open Patent Application 2004-111432, which was filed earlier by the present inventors. In the present semiconductor substrate processing, sputtering of material of the processing chamber sidewall 205a is restrained. However, nonvolatile reaction byproducts produced from slightly sputtered sidewall material are attached to the downstream region 206a where plasma attack occurs less frequently. Over a very long period of time, the accumulated byproducts may be broken up and stripped off to become particles on semiconductor substrates, or particles 207a on the wall surface.

During the particle removal processing in this embodiment, as shown in FIG. 2B-1, RF power is applied in phase to the upper antenna 201b with a potential Vpp of 100 to 300 V (shown in solid line) and to the lower electrode 202b with a potential Vpp of 50 to 400 V (shown in dashed line).

In this embodiment, the particle removal processing is performed with no dummy substrate mounted on the electrode, and the amplitude of voltage applied to the lower electrode is set to a relatively low voltage of 50 V for reducing plasma damage to the electrode surface. Alternatively, the particle removal processing can be performed with a dummy substrate being mounted. In the in-phase condition, the maximum plasma potential is determined to be the higher of the potentials of the upper antenna 201b and of the lower electrode 202b. Plasma spreads downstream when the potential of the upper antenna 201b is high, even if the potential of the lower electrode 202b is low.

In the particle removal processing, as shown in FIG. 2B-2, it is confirmed that at the moment when the lower electrode 202b and the upper antenna 201b are both negative, plasma 204b seeks ground and spreads on the processing chamber sidewall 205b and the inner wall of the downstream region 206b. Electrons 203b in the plasma are incident on the inner wall, deposited film, and particles 207b in the downstream region 206b to facilitate the stripping of the particles.

According to the invention, it is important to set the pressure to a high level for removing the stripped particles along with the gas flow. The pressure is set to 10 Pa in this embodiment, but an even higher pressure is preferable for evacuation of particles.

Reference is now made to FIGS. 3A and 3B for describing the necessity of setting the pressure to a high level to perform the particle removal processing. FIGS. 3A and 3B show the estimated scattering distance of stripped particles. The estimation is made in the following condition: a gas having a molecular weight of 32 g/mol is passed at a flow rate of 2000 ccm through a gas flow channel having a cross section of 0.1 m² (equivalent to the cross section of a gap between the wall of a vacuum chamber with a diameter of 500 mm and a lower electrode with a diameter of 350 mm in the chamber). In the gas flow channel, particles having a density of 1 g/cm³ are launched at an initial velocity of 50 m/s against the flow. The estimation is based on the distance that the particles fly from the launch point for various particle diameters and pressure conditions. In the estimation, the frequency of collision between the gas and the particles is estimated from the particle diameter and pressure, and the momentum change at the collision is integrated to determine the trajectory.

The particles launched from the wall have a scattering distance that sharply decreases and follows the gas flow as the pressure becomes higher. Particles with a greater diameter have a longer scattering distance. It can be said that in order to prevent particles from scattering upstream of the processing chamber, the pressure is preferably 10 Pa or higher, and more preferably 20 or 30 Pa or higher. The possibility of discharging at these pressures is limited by a certain maximum pressure that depends on the plasma generation method and configuration. If the number of particles is greater, discharge processing at a lower pressure may adversely cause more particles to scatter upstream of the processing chamber and lead to increased particles on semiconductor substrates.

Reference is now made to the pressure monitoring system 109 in FIG. 1 to describe a pressure monitoring method in the plasma etching apparatus of the invention. The plasma etching apparatus according to the invention comprises a low-pressure gauge (P1) for zero to over ten pascal, and a high-pressure gauge (P2) for zero to a hundred and several tens of pascal. A valve V11 is placed between the low-pressure gauge P1 and the processing chamber 101, and a valve V21 is placed between the pressure gauge P2 and the processing chamber 101. A piping, provided between the low-pressure gauge P1 and the evacuation system 111a, can be gated by a valve V12. Similarly, another piping and a valve V22 are placed between the high-pressure gauge P2 and the evacuation system 111a.

In the plasma etching apparatus of the invention, during processing the semiconductor substrate 104 in the processing chamber 101, the valve V11 is opened and the valve V12 is closed to use the gauge P1 of the lower pressure range for monitoring the pressure of the processing chamber 101. At this time, the valve V21 is closed and the valve V22 is opened to evacuate and zero calibrate the gauge P2 of the higher pressure range.

On the other hand, during the particle removal processing, the valve V21 is opened and the valve V22 is closed to use the gauge P2 of the higher pressure range for monitoring the pressure of the processing chamber, whereas the valve V11 is closed and the valve V12 is opened to zero calibrate the pressure gauge P1. In this way, the reproducibility of pressure at processing time can be maintained without evacuating the processing chamber to high vacuum.

In this embodiment, this mechanism is used to maintain the processing chamber 101 at a pressure of about 10 Pa, which is above the pressure processing semiconductor substrate, even during the interval between the semiconductor substrate processing and the particle removal processing. A small number of particles stripped by temperature variation during evacuation to high vacuum are thereby restrained from scattering upstream. The pressure of the processing chamber 101 does not necessarily need to be above 10 Pa during the interval. A pressure of several pascal or higher, instead of the typical pressure evacuated to high vacuum below 1 Pa, would be effective at reducing particles on semiconductor substrates, especially for fine particles.

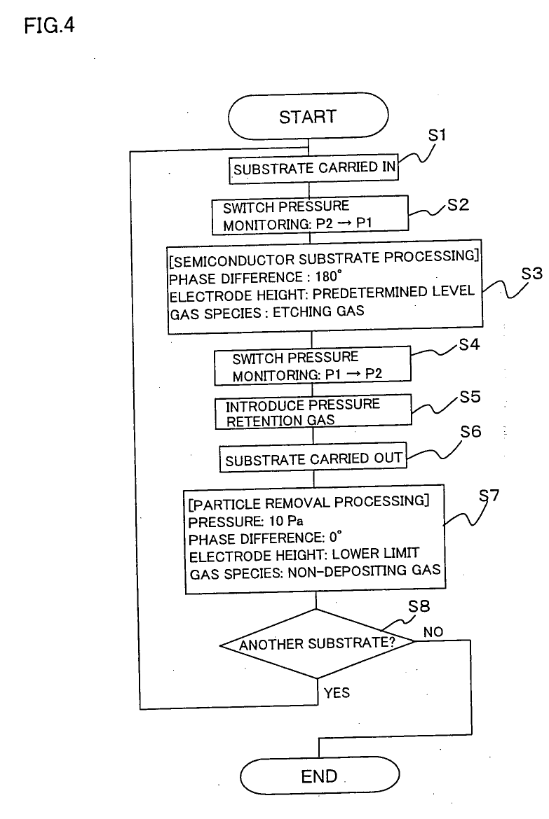

Reference is now made to the flow chart in FIG. 4 to describe an example of continuously processing a semiconductor substrate. In this plasma etching apparatus, the transfer chamber and the processing chamber are both maintained at about 10 Pa by introducing inert gas for pressure retention.

In this embodiment, a semiconductor substrate is first carried into the processing chamber (S1). Pressure monitoring is then switched to the low-pressure gauge P1 (S2). The semiconductor substrate is processed by setting the phase to 180° and the electrode height to a predetermined level and by performing an etching process using etching gas at a processing pressure of 4 Pa (S3). Subsequently, pressure monitoring for the processing chamber is switched to the high-pressure gauge P2 (S4). Ar gas is introduced as a pressure retention gas (S5) to maintain the pressure at 10 Pa. In this condition, the semiconductor substrate is carried out (S6). Next, the particle removal processing is performed without dummy substrate (S7). Although not shown, in the particle removal processing, the electrode height is set to its lower limit and Ar gas for pressure retention is stopped. As a non-depositing gas, 2000 ccm of O₂ is introduced, and the pressure is maintained at 10 Pa. A predetermined electric power is applied to the upper antenna and the lower electrode for 5 seconds with a phase difference of 0°. Subsequently, with the introduction of O₂ gas being continued and the pressure maintained, application of power is stopped for 1 second. Power is then applied again for 5 seconds. Subsequently, O₂ gas is stopped and Ar gas for pressure retention is introduced to maintain the pressure at 10 Pa. After the particle removal processing described above is performed, the next substrate is carried into the chamber.

The particle removal of this embodiment is performed for each wafer. However, the particle removal method of the invention may be performed for every 13 or 25 wafers, or arbitrarily for every several wafers, rather than for every wafer of semiconductor substrate being processed. Moreover, in this embodiment, the pressure of the processing chamber is maintained between consecutive iterations of plasma processing and Ar gas is used for restraining particles from scattering. However, an inert gas such as N₂, or O₂ or F (fluorine) containing gas is also effective for evacuation of particles. Furthermore, the gas flow is not necessarily needed between consecutive iterations of semiconductor substrate processing when the amount of particles on semiconductor substrates due to particles scattering between the processes is small.

The particle removal processing (S7) of the above embodiment is described with reference to an example of applied power being turned on and off. However, in order to ensure as much discharge time as possible for cleaning deposits, the processing may be composed of several steps at varied power without stopping discharge, or of only a single step.

The term “in phase” or “equal phase” used herein refers to a phase difference of voltage amplitude in the range of 0°±30°. The term “opposite phase” used herein refers to a phased difference in the range of 180°±10°.

The embodiment is described for a phase of 180° or 0°. However, the relationship in polarity of potential between the antenna and the lower electrode with a phase in the range of 170° to 190° or −30° to 30° is similar to that with a phase of 180° or 0°, respectively, for 80% or more of the total time, and thus obviously achieves an effect similar to that for a phase of 180° or 0°. This is confirmed by measurements of plasma potential.

The above embodiment is described with reference to an example of RF power supply for the antenna and the lower electrode having a frequency of 800 kHz. However, it is to be understood that a frequency of several megahertz is also effective because electrons can follow the potential very rapidly.

In this embodiment, from a throughput point of view, the particle removal discharge is performed for each substrate with no dummy substrate being mounted. However, the discharge may be performed for each lot with a dummy substrate being mounted and processed at a higher power.

The embodiment of the invention is described with reference to an example of a plasma etching apparatus without magnetic field. However, the invention is also applicable to a plasma etching apparatus with magnetic field and a RIE plasma etching apparatus of the parallel plate type.

What is claimed is:

1. A particle removal method in a plasma etching apparatus including an upper antenna and a lower electrode opposed thereto in a vacuum processing chamber, the lower electrode being capable of mounting a semiconductor substrate; gas introducing means; evacuating means; means for controllably applying RF power at a common frequency to the upper antenna and the lower electrode and for controlling voltage phase of the RF power between equal phase and opposite phase; and means for vertically moving the lower electrode, the method comprising:
during a semiconductor substrate processing, applying RF power to the upper antenna and the lower electrode in opposite phase of voltage; and
when the semiconductor substrate is not processed, performing discharge in the presence of non-depositing gas, applied power for the upper antenna and applied power for the lower electrode being in equal phase of voltage, one of the applied powers having a voltage amplitude of 100 V or more, and the height of the lower electrode being lower than the height during the semiconductor substrate processing.

2. A particle removal method according to claim 1, wherein
the RF power applied in opposite phase has a voltage phase difference of 170° to 190°, and the RF power applied in equal phase has a voltage phase difference of −30° to 30°.

3. A particle removal method according to claim 1, wherein
when the semiconductor substrate is not processed, discharge is performed at a higher pressure than a semiconductor substrate processing pressure.

4. A particle removal method according to claim 1, wherein
when the semiconductor substrate is not processed, while introduction of the non-depositing gas is continued, the applied power is varied or application and non-application of power are repeated twice or more.

5. A particle removal method according to claim 1, wherein
when two or more semiconductor substrates are consecutively processed,
introduction of the non-depositing gas is continued between the processes for the semiconductor substrates, and the pressure of the processing chamber is kept higher than a semiconductor substrate processing pressure.

6. A particle removal method according to claim 1, wherein
when two or more semiconductor substrates are consecutively processed,
while introduction of the non-depositing gas is continued between the processes for the semiconductor substrates, discharge is performed with the pressure of the processing chamber being kept higher than a semiconductor substrate processing pressure.

7. A particle removal method according to claim 1, wherein
when two or more semiconductor substrates are consecutively processed,
while introduction of the non-depositing gas is continued between the processes for the semiconductor substrates, discharge is performed with the pressure of the processing chamber being kept higher than a semiconductor substrate processing pressure, the discharge being such that the applied power is varied or application and non-application of power are repeated twice or more.

8. A plasma etching apparatus comprising:
an upper antenna and a lower electrode opposed thereto in a vacuum processing chamber, the lower electrode being capable of mounting a semiconductor substrate;
a pressure gauge system for monitoring the pressure of the processing chamber during plasma processing;
gas introducing means;
evacuating means;
means for controllably applying RF power at a common frequency to the upper antenna and the lower electrode and for controlling voltage phase of the RF power between equal phase and opposite phase; and
means for vertically moving the lower electrode, wherein
the pressure gauge system has two pressure gauges of different ranges for monitoring the pressure of the processing chamber and includes means for evacuating and zero calibrating each of the pressure gauges without the intervention of the processing chamber even when the processing chamber is not evacuated to high vacuum, and the apparatus performs a particle removal method including:
during a semiconductor substrate processing, applying RF power to the upper antenna and the lower electrode in opposite phase of voltage; and
when the semiconductor substrate is not processed, performing discharge in the presence of non-depositing gas, applied power for the upper antenna and applied power for the lower electrode being in equal phase of voltage, one of the applied powers having a voltage amplitude of 100 V or more, and the height of the lower electrode being lower than the height during the semiconductor substrate processing.

9. A plasma etching apparatus according to claim 8, wherein
each of the two pressure gauges of different ranges for monitoring the pressure of the processing chamber has a valve to the processing chamber, and between each of the pressure gauges and the valve is provided another valve to evacuation piping.

10. A plasma etching apparatus according to claim 8, wherein the apparatus performs a particle removal method in which:
the RF power applied in opposite phase has a voltage phase difference of 170° to 190°, and the RF power applied in equal phase has a voltage phase difference of −30° to 30°.

11. A plasma etching apparatus according to claim 8, wherein the apparatus performs a particle removal method in which:
when the semiconductor substrate is not processed, discharge is performed at a higher pressure than a semiconductor substrate processing pressure.

12. A plasma etching apparatus according to claim 8, wherein the apparatus performs a particle removal method in which:
when the semiconductor substrate is not processed, while introduction of the non-depositing gas is continued, the applied power is varied or application and non-application of power are repeated twice or more.

13. A plasma etching apparatus according to claim 8, wherein the apparatus performs a particle removal method in which:
when two or more semiconductor substrates are consecutively processed,
introduction of the non-depositing gas is continued between the processes for the semiconductor substrates, and the pressure of the processing chamber is kept higher than a semiconductor substrate processing pressure.

14. A plasma etching apparatus according to claim 8, wherein the apparatus performs a particle removal method in which:
when two or more semiconductor substrates are consecutively processed,
while introduction of the non-depositing gas is continued between the processes for the semiconductor substrates, discharge is performed with the pressure of the processing chamber being kept higher than a semiconductor substrate processing pressure, the discharge being such that the applied power is varied or application and non-application of power are repeated twice or more.
